(19) United States
(12) Patent Application Publication
(10) Pub. No.: US 2011/0244603 A1
(43) Pub. Date: Oct. 6, 2011

(54) CUSTOMIZED METALLIZATION PATTERNS DURING FABRICATION OF SEMICONDUCTOR DEVICES

(76) Inventor: Michael Dovrat, Modi'in (IL)

(21) Appl. No.: 13/139,408

(22) PCT Filed: Dec. 10, 2009
(86) PCT No.: PCT/IL09/01177

§ 371 Date: Jun. 13, 2011

Related U.S. Application Data
(60) Provisional application No. 61/121,738, filed on Dec. 11, 2008.

(51) Int. Cl. H01L 21/66

(52) U.S. Cl. 438/7; 257/E21.53

(57) ABSTRACT

Embodiments of the invention are directed to a system and method of depositing material on a polycrystalline semiconductor substrate. The method may comprise detecting characteristics of polycrystalline semiconductor substrate, generating image data of a customized pattern of lines based on the characteristics of the substrate and depositing material from one or more nozzles on the substrate according to the image data of the customized pattern. The characteristics may include grain boundaries of the substrate and spatial variations in sheet resistance and/or the minority carrier lifetime of the substrate.

### BACKGROUND OF THE INVENTION

In the field of photovoltaic solar cells, the aim is usually to deliver a given power output at the lowest possible price. This aim demands both high efficiency and minimal production costs. As the raw material can be a major contributor to cost, it is desirable, whenever possible, to use poly-crystalline silicon rather than high-purity single-crystal silicon. A disadvantage of the use of poly-crystalline silicon, however, is that it contains many efficiency-lowering defects and an inherent non-uniformity of various electrical and physical characteristics of the substrate.

Semiconductor devices, such as photovoltaic cells are presently fabricated commercially by non-customized processes, which are complex, time consuming, expensive and not suitable for customized fabrication. In particular, the deposition process of a metallization grid on front surfaces (the surface receiving the sunlight) of solar cells is based on a single metallization pattern which do not take into account the unique characteristics of each poly-crystalline substrate.

For example, sheet resistance values within a poly-crystalline substrate may vary at different regions of the substrate. It is known in the art that at relatively high values of sheet resistance, the spacing between fingers of the metallization grid should be smaller than at lower values of sheet resistance. Accordingly, a metallization grid for a poly-crystalline substrate that is designed based on an average value of the sheet resistance would not be efficient and would result in current loss. A cost-effective method for the production of customized semiconductor devices that would take into account the unique characteristics of each poly-crystalline substrate is highly desired.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 is a high level block diagram of a deposition system for producing customized metallization patterns during manufacture of semiconductor devices according to some embodiments of the present invention;

FIG. 2 is a flowchart of a method for deposition of materials in customized patterns during fabrication of semiconductor devices according to embodiments of the invention;

FIG. 3 is an illustration of an exemplary map showing grain boundaries of polycrystalline semiconductor surface helpful in demonstrating embodiments of the invention;

FIG. 4 is an illustration of an exemplary customized metallization pattern on a polycrystalline semiconductor surface according to embodiments of the invention; and

FIGS. 5A and 5B illustrate a method of generating an exemplary customized metallization pattern on a polycrystalline semiconductor surface according to embodiments of the invention.

It will be appreciated that for simplicity and clarity of illustration, elements shown in the drawings have not necessarily been drawn accurately or to scale. For example, the dimensions of some of the elements may be exaggerated relative to other elements for clarity. Further, where considered appropriate, reference numerals may be repeated among the drawings to indicate corresponding or analogous elements. Moreover, some of the blocks depicted in the drawings may be combined into a single function.

### DETAILED DESCRIPTION OF EMBODIMENTS OF THE INVENTION

In the following detailed description, numerous specific details are set forth in order to provide a thorough understanding of the invention. However, it will be understood by those of ordinary skill in the art that the present invention may be practiced without these specific details. In other instances, well-known methods, procedures, components and circuits may not have been described in detail so as not to obscure the present invention.

Embodiments of the invention are directed to a method and system for customized material deposition on a substrate based on real-time online identification and mapping of non-uniformity of various characteristics of the substrate. Exemplary embodiments of the invention are directed to a method for applying metallization grid on a surface of a multi-crystalline semiconductor substrate or thin film during manufacture of a semiconductor device according to a customized metallization pattern. For example, the method may be used for applying metallization grid on a multi-crystalline semiconductor substrate used as a front surface of a photovoltaic cell (solar cell). The metallization pattern is usually applied to the front surface (the surface receiving the sunlight) of the solar cell in order to create electrical contacts. According to other embodiments of the invention, the method may be used for applying metallization grid a thin film made of poly-crystalline semiconductor within a semiconductor device, such as thin film transistor.

It should be understood to a person skilled in the art that embodiments of the invention are not limited in this respect and the method of applying metallization according to a customized metallization pattern may be applicable to may other applications. Further, it should be understood to a person skilled in the art that embodiments of the invention are likewise applicable to deposition of non-metallic materials. For ease of explanation and clarity, embodiments of the invention are mainly described with respect to customized metallization pattern of a metallization network on a front side of a photovoltaic cell.

The term “substrate” as referred herein includes both multi-crystalline semiconductor substrate and a deposited thin film which includes polycrystalline semiconductors. The semiconductor substrate may include for example, Silicone (Si), Galium Arsenide (GaAs) and Copper indium gallium selenite (CIGS) and other semiconductor materials.

The method may be applied to a mass production of photovoltaic cells using a drop-on-demand deposition system such as an inkjet printer. According to an exemplary embodiment of the invention the deposition system may be an inkjet system as described in International patent application no. PCT/IL2007/001468, which is incorporated herein by reference. It should be obvious to a person skilled in the art, however, that embodiments of the invention are not limited in that respect and the deposition system may include any other inkjet printing system, aerosol jetting systems or dispensers.

The method may include identifying unique characteristics of the substrate in real-time, designing a customized pattern based at least on the unique characteristics and depositing a metallization grid according to the customized pattern. The customized pattern may be based on an optimization calculation that takes into account one or more unique characteristics of the substrate and in particular, the non-uniformity or such characteristics within the substrate. The customized pattern may be determined based on at least one of the following non-exhaustive list of characteristics: location of grain boundaries of the substrate, non-uniformity in sheet resistance of the substrate, minority carrier lifetime map of the device, size and shape of the substrate and production costs.

A poly-crystalline semiconductor substrate may possess inherent inhomogeneous characteristics due to the poly-crystalline nature of the material and to impurities within the material. The grain boundaries of the poly-crystalline semiconductor substrate are regions of enhanced recombination. This phenomenon contributes to unwanted current loss and heating in these regions, which results in decrease in the efficiency of the device. In addition, the manufacturing processes may generate additional features of inhomogeneity or spatial variations within the substrate, such as, non-uniformity of electrical and/or physical properties. For example, an ion diffusion process that results in a non-uniform ion diffusion pattern within the substrate may cause non-uniform junction depth values and/or sheet resistance values in different regions of the substrate. Temperature changes during processing may also increase the inhomogeneity of various characteristics of the substrate.

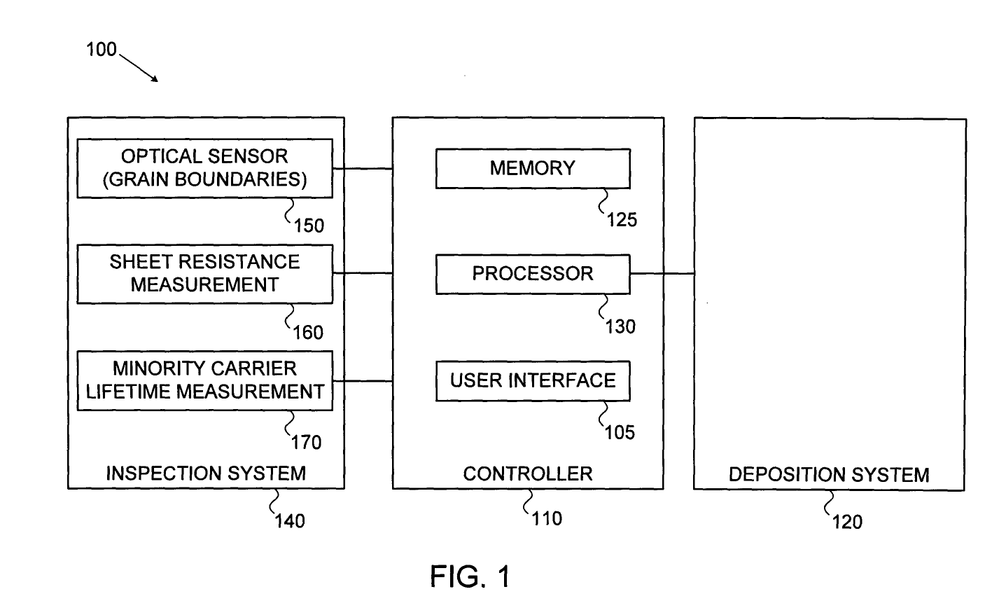

According to embodiments of the invention, a deposition system that is capable of generating customized pattern, in real-time, based on the identification of the unique inhomogeneous characteristics of a poly-crystalline semiconductor substrate is provided. Reference is now made to FIG. 1, which schematically illustrates an exemplary deposition system 100 according to embodiments of the present invention. In some demonstrative embodiments of the invention, system 100 may include a deposition unit or device 120, a processing or controlling device 130 and one or more inspection or measurement devices, collectively referred to inspection system 140. Deposition unit 120 may be an inkjet printing system or any other drop-on demand printing system. An exemplary inkjet printing system may include one or more printing heads, each having one or more nozzles through which depositing material such as conducting ink may be jetted onto a substrate. Deposition unit 120 may be an inkjet system as described in International patent application No. PCT/IL2007/001468. As understood to a person skilled in the art, the inspection devices may be stand-alone devices or may be combined into one system.

Measurement or inspection system 140 may include an optical detector 150, such as camera to capture image data of the substrate for at least the purpose of determine the exact shape and size of the substrate and mapping the grain boundaries of the substrate. It should be understood to a person skilled in the art that embodiments of the invention may be applicable to printing on a single crystalline substrate, in which case the operation of mapping grain boundaries is not relevant.

Inspection system 140 may further include a sheet resistance mapping unit 160 to map the emitter sheet resistance within the substrate. Sheet resistance mapping unit 160 may perform measurements of emitter sheet resistance using any suitable method, such as for example performing a 4-point scanning probe using for example the mapping unit sold under the trade name Sherescan by SunLab B.V of Petten, the Netherlands. It should be understood to a person skilled in the art that embodiments of the invention are not limited to using such a device and any other sheet resistance mapping unit may be likewise applicable. According to embodiments of the invention, the sheet resistance mapping data may be collected using any non-contact, not-destructive measurement method, using for example, products sold by SemiLab co. of Budapest, Hungary.

Inspection system 140 may further include, additionally or alternatively to sheet resistance mapping unit 160, a minority carrier lifetime mapping unit 170 to map the minority carrier lifetime in the bulk of the photovoltaic cell. Minority carrier lifetime mapping unit 170 may perform measurements of lifetime of the minority carrier using any suitable method, such carrier density imaging, light beam inducted current (LBIC), photoluminescence, time resolved photoluminescence characterization and others.

Processing or controlling unit 110 may include a processor 130 to receive data from inspection system 140 and to generate a customized pattern of conductive grid lines based on the received data. Processing unit may execute the methods described herein. Controlling unit 110 includes a user interface 105, a memory 125 and a processor 130. Controlling unit may be implemented on a general purpose microcomputer. Although controlling unit is represented herein as a standalone system, it is not limited to such, but instead can be coupled to other computer systems (not shown) via a network (not shown). Controlling unit 110 may include storage medium, such as memory 125 having stored thereon instructions including optimization algorithms from generating the customized pattern in real-time. An implementation of memory 125 may include a random access memory (RAM), a hard drive and a read only memory (ROM). User interface 705 includes an input device, such as a keyboard or speech recognition subsystem, for enabling a user to communicate information and command selections to processor 710. User interface 105 may include one or more output devices such as a display or a printer, and one or more input devices such as a keyboard, a mouse, track-ball, or joy stick Controlling unit 110 may further control deposition unit 120 and the deposition process.

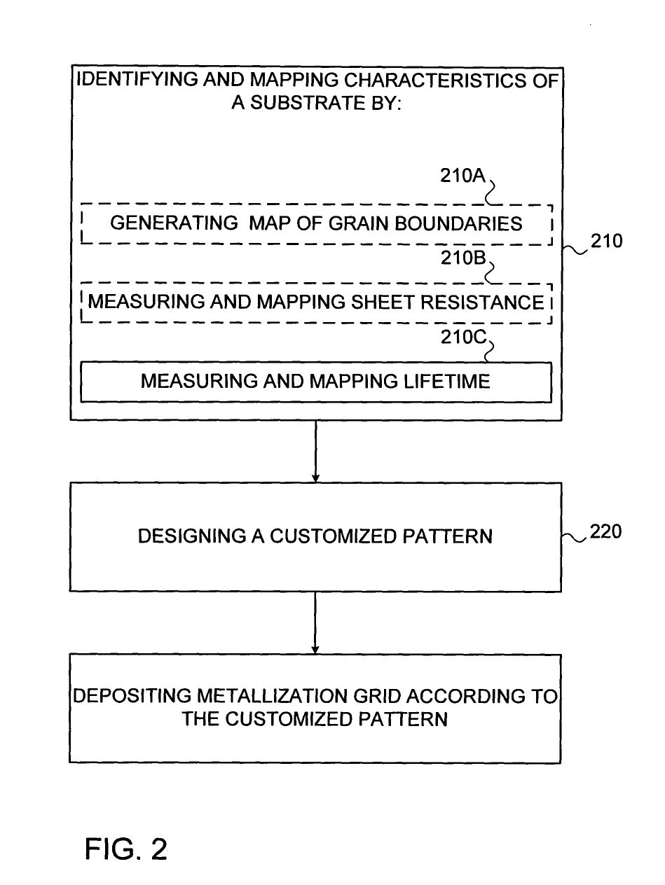

Reference is now made to FIG. 2, which is a flowchart of a method for deposition of materials in customized patterns during fabrication of semiconductor devices according to embodiments of the invention. According to some embodiments, the metallization grid or metallization network may generally follow the grain boundaries locations, where additional metal lines may be deposited within each mono-crystal, if required, for example in areas showing higher emitter sheet resistively and/or short minority carrier lifetime.

According to exemplary embodiments of the invention, as indicated at box 210 of FIG. 2, the method may include identifying and mapping unique characteristics of the substrate in real-time. Identifying the unique characteristics of the substrate may include for example, determining the exact shape and size of the substrate and mapping the grain boundaries of the substrate (box 210A), measuring and mapping differences in sheet resistance of the substrate (box 210B), and measuring and mapping differences in lifetime of minority charge carriers within the substrate (box 210C).

There are a number of non-destructive measurements methods for identification of polycrystalline grain boundaries. According to embodiments of the invention, mapping the grain boundaries of the substrate may be performed using an optical sensor, such as high resolution camera. Prior to capturing of the image data, the environmental conditions of lighting may be adjusted to achieve an optimal image by controlling various parameters, such as whether to use side illumination, dark field, light wavelength, polarization of light, differential interference contrast and the like. The image data may be captured in real-time during the manufacturing process of the semiconductor device. For photovoltaic cells made of poly-crystalline substrates that are not thin films, the data capturing process may be performed on the bare substrate prior to coating. For thin-film photovoltaic cells, a thin film made of a poly-crystalline material may be deposited on substrate and the data capturing process may be performed either before or after additional deposition of other thin films, such as an anti-reflective coating that is usually applied onto the surface of the polycrystalline semiconductor.

The identification of the substrate size and mapping of the grain boundaries may include using image processing algorithms such as for example, edge detection, line detection, texture analysis and other. For example, processing unit 110 may receive image data from unit 150 and may process the data to obtain grain boundary mapping data. The image processing algorithms may be stored in memory 125 of processing unit 110 or alternatively in another processing unit within inspection system 140 or in another external processing unit. The image processing may generate a map of grain boundaries for the substrate (wafer) at a desired resolution. The map may be stored in memory 125 of processing unit 110 and may be used as input for the calculation of the customized pattern.

FIG. 3 is an illustration of an exemplary map showing grain boundaries of polycrystalline semiconductor surface helpful in demonstrating embodiments of the invention. As illustrated, exemplary substrate 300 includes grains of various sizes located randomly within the substrate. For example, grain 310 has an area roughly 10 times smaller than grain 320.

Back to FIG. 2, identifying the unique characteristics of the substrate may include for example, generating a map of the distribution of sheet resistance of the substrate (box 210B). The measurement and mapping of the sheet resistance may be performed by any suitable method such as the 4-point scanning method. According to embodiments of the invention the method of mapping may include measuring with a capacitive probe, measuring eddy currents or light-induced photovoltaic measurement. The sheet resistance map may be stored in memory 125 of processing unit 110 and may be used as input for the calculation of the customized pattern.

According to embodiments of the invention, identifying the unique characteristics of the substrate may include for example, mapping of the distribution of the minority carrier lifetime within the substrate (box 210C). The measurement of minority carrier lifetime may be performed by any suitable method including, but not limited to, carrier density imaging, light beam induced current, photoluminescence and time-resolved photoluminescence characterization. The minority carrier lifetime map may be stored in memory 125 of processing unit 110 and may be used as input for the calculation of the customized pattern.

According to embodiments of the invention, the method may include designing a customized pattern based at least on the identified unique characteristics of the substrate, such as the size of the wafer, the grain boundaries, the sheet resistance and/or the minority carrier lifetime (box 220) Processor 130 may perform an optimization calculation to determine an optimal customized metallization pattern that would minimize current losses and increase the solar cell efficiency based on at least on the information received from units 150, 160 and 170. For example, the desired customized pattern may be calculated with predetermined desired constraints. According to some embodiments, the constraints may be that the total area covered by the metallization lines and additionally or alternatively that the total length of the metallization grid may not exceed the desired values.

The optimization calculation may determine a pattern of metallization lines in a photovoltaic cell optimized relative to photo-current collection performance of the photovoltaic cell.

The optimization calculation may be based on additional information, such as for example, the relative coverage by metallization (shaded area). According to embodiments of the invention, the optimization algorithm may model a metallization network on the front surface of a poly-crystalline solar cell and further the current flow in such a metallization network. Then, the optimization algorithm may calculate current losses and heat dissipation in the solar cell. The optimization calculation may include one or more constraints related for example to cost considerations. An example for such a constraint is the amount of material to be deposited. The algorithm may calculate the optimal metallization pattern with respect to solar cell efficiency given a certain amount of material to be deposited. The algorithm may further calculate the prospected increase in efficiency upon increasing the amount of material to be used as a metallization grid. This scheme may enable a manufacturer to determine customized cost-benefit optimum in real-time per wafer or device. According to embodiments of the invention, the metallization pattern may be customized according to the exact size of the wafer and may produce reduced or enlarged according to the actual size of the wafer.

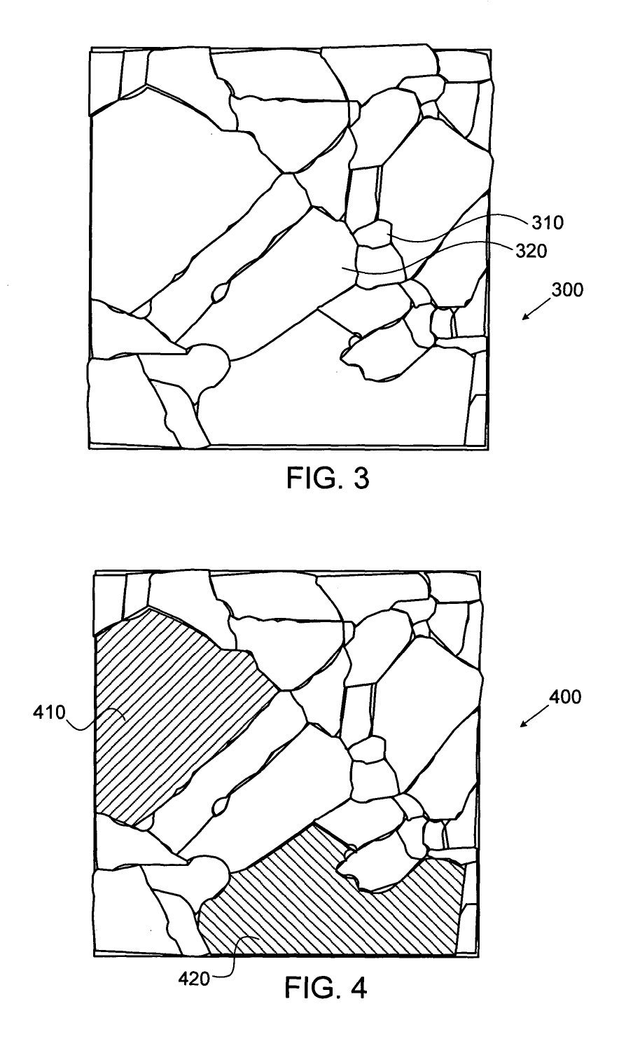

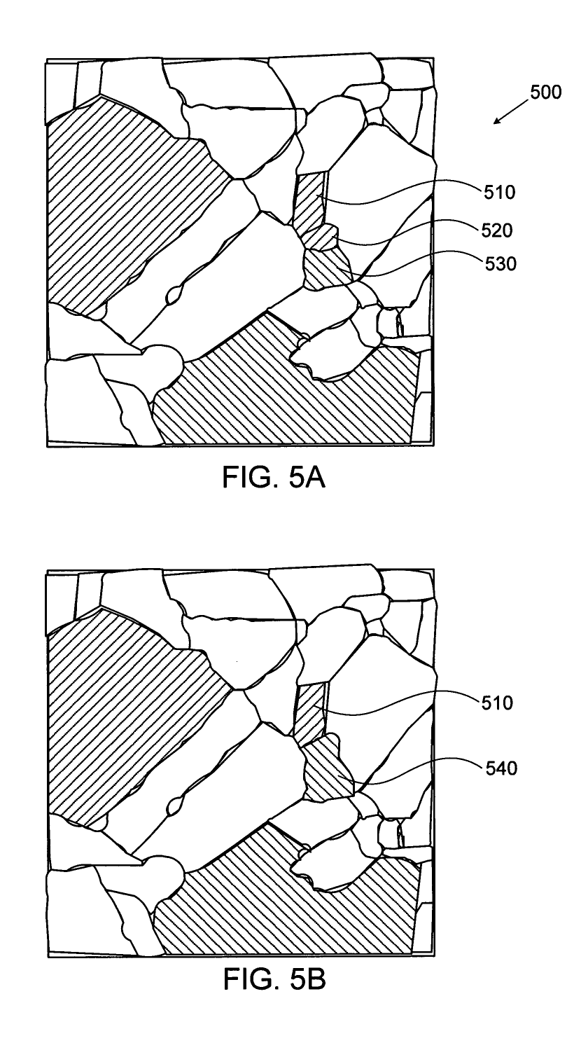

The calculation may be an iterative calculation starting with a pattern of lines residing on the grain boundaries, as illustrated by FIG. 3. The motivation for correlating between the grain boundaries and the metallization grid results from the desire to increase the efficiency of the solar cells. This may be viewed as effectively fabricating small mono-crystalline solar cells in random shapes following the randomness of the sizes and shapes of the grains within the poly-crystalline semiconductor. Efficiency may decease, however, if a grain having a small area, smaller than a desired threshold may be encircled by a metallization line. Accordingly, a small grain, smaller than a desired threshold may be merged for example with another small neighboring grain into a single area as illustrated by FIGS. 5A and 5B and additional parallel metallization lines may be added to the pattern within at least some of the encircled areas as illustrated by FIG. 4.

The customized pattern may include parallel metallization lines within at least some of the areas encircled by a metallization line crystal, each defining a mono-crystal. The spacing between lines in different areas may be different from each other. FIG. 4 is an illustration of an exemplary customized metallization pattern on a polycrystalline semiconductor surface according to embodiments of the invention showing two areas patterned with different spacing between metallization lines. As illustrated, exemplary substrate 400 includes grains of various sizes located randomly within the substrate. For example, based on the inspection methods detailed herein, it was determined that area 410 corresponds to higher emitter sheet resistivity than area 420. Accordingly, the metallization lines within area 410 are designed to be more dense, namely having a smaller distance between each line, that the lines within area 420 where the distance between adjacent lines is larger. Further, the exemplary substrate 400 may be customized such that metallization lines may not be added onto certain regions identified with a short lifetime of minority charge carriers so as to minimize excessive current leakage through recombination. Other additional or alternative considerations may be taken into account when determining the customized pattern.

FIGS. 5A and 5B are illustrations of an exemplary metallization grid with merged areas demonstrating a method of generating an exemplary customized metallization pattern on a polycrystalline semiconductor surface according to embodiments of the invention. As illustrated, exemplary substrate 500 includes grains of various sizes located randomly within the substrate. For example, the size of grain 510 is larger that a threshold size (area) whereas the size of both grain 520 and 530 is smaller that the threshold size. According to embodiments of the invention, grains 520 and 530 are merged into one area 540, which larger than the threshold size. The merging process may be done in iterations until the metallization network would not contain any areas smaller than the threshold area.

According to embodiments of the invention, the iterative procedure may be processed with the constraint of the amount of conductive material to be deposited on the substrate. Based on this desired amount of conductive material, the processor may choose which small grain would remain in the metallization network and which grains would be merged. For example, the procedure may start with calculating the required total length of the network (L₀) based on the amount of conductive material (taking into consideration the width of the line and its height). The calculated length (L) of the network in a given iteration is compared with the total required length (L₀). If the total required length (L₀) is smaller that the calculated length (L), the smallest grains in the network are merged with their nearest and smallest neighbors and a new length is re-calculated. In the subsequent iterations, the procedure continues and compares the total required length (L₀) with the new calculated length (L). The procedure may be repeated until the total required length (L₀) is equal or larger than the calculated length of the metallization network.

According to alternative embodiments of the invention, instead of having the total amount of material as a constraint to the calculation, the basis of the calculation is comparing the cost of the deposited material to the conversion efficiency of the photovoltaic cell. The photo-current collection efficiency of the photovoltaic cell may be calculated for a given metallization network based on the measured parameters of sheet resistance and minority charge carrier lifetime.

According to embodiments of the invention, as indicated at box 230 of FIG. 2, the method may include depositing conductive material to form a metallization grid on the inspected semiconductor substrate according to the customized pattern. For example, the optimized pattern of metallization lines may include lines of variable height and width. The height and/or width of each of the lines may be designed according to the current flow intended to be carried by the line. The metallization grid may be designed to minimize the resistance of the metal line without increasing the shaded areas of the photovoltaic cell. The lines may be designed to be deposited in layers and the number of layers may be determined according to a desired height. The shape of the line may be designed as having a tapered or wedge-like cross section. The tapered cross section of the lines may minimize shading of the wafer. Such lines may increase the efficiency of the solar cell as the shadow area that is covered from the sun is reduced.

The metal lines may be printed by a printing system that enables multi-pass printing to create thinner and higher contact lines capable of carrying the same amount of current as standard wider and “shorter” contacts. Such lines may increase the efficiency of the solar cell as the shadow area that is covered from the sun is reduced.

According to exemplary embodiments of the invention, the metallization grid used to collect current may emulate the structure of the vascular system within a leaf. Accordingly, the customized pattern may be designed with metallization lines having different width and height that changes according to the amount of current intended to flow through them. Areas of the solar cell from which relatively lower current should be collected may include narrow and short lines that may be evenly or randomly distributed within that area and these narrow lines may lead to wider and higher lines to be accommodated for larger currents intended to flow through them. The metallization grid may further include bus lines that are intended to carry larger currents. According to other embodiments of the invention, the bus lines may be excluded from the metallization pattern. According to embodiments of the invention, optionally, the metallization grid may be further inspected after the first deposition operation. If needed, a second deposition process may be performed to correct any defects that were detected.

Although embodiments of the present invention are described with respect to metallization pattern on the front surface of a photovoltaic cell, it should be understood to a person skilled in the art that embodiments of the present invention may be used for back contact metallization as well.

Some embodiments of the present invention may be implemented in software for execution by a processor-based system. For example, embodiments of the invention may be implemented in code and may be stored on a storage medium having stored thereon instructions which can be used to program a system to perform the instructions. The storage medium may include, but is not limited to, any type of disk including floppy disks, optical disks, compact disk read-only memories (CD-ROMs), rewritable compact disk (CD-RW), and magneto-optical disks, semiconductor devices such as read-only memories (ROMs), random access memories (RAMs), such as a dynamic RAM (DRAM), erasable programmable read-only memories (EPROMs), flash memories, electrically erasable programmable read-only memories (EEPROMs), magnetic or optical cards, or any type of media suitable for storing electronic instructions, including programmable storage devices.

Such a system may include components such as, but not limited to, a plurality of central processing units (CPU) or any other suitable multi-purpose or specific processors or controllers, a plurality of input units, a plurality of output units, a plurality of memory units, and a plurality of storage units. Such system may additionally include other suitable hardware components and/or software components.

Although embodiments of the present invention are described with respect to metallic materials, the invention is not limited in this respect and other materials may be used such as materials suitable for altering surface properties, materials suitable for etching, materials suitable for passivation, materials suitable for changing surface physical parameters, such as surface free energy or hydrophobicity, material containing glass frits, conductive material, insulating materials, metal-organic compounds, acids, and any combination thereof.

According to other embodiments of the invention, the methods and system described above may be used in photolithography applications to design an optimal pattern customized according to the characteristics of the semiconductor substrate and to perform direct selective etching at the desired areas. Using the method according to embodiments of the invention may eliminate the need for producing a predefined photolithographic mask, which cannot be customized to each device or substrate. According to embodiments of the invention, the methods and system described above may be used in additional applications such as producing a customized data for an electron-beam lithography apparatus, laser ablation apparatus or etching apparatus based on real-time detection and identification of physical and electrical properties of the substrate the undergoes further processing.

While certain features of the invention have been illustrated and described herein, many modifications, substitutions, changes, and equivalents may occur to those of ordinary skill in the art. It is, therefore, to be understood that the appended claims are intended to cover all such modifications and changes as fall within the true spirit of the invention.

1. A method of depositing material on a crystalline semiconductor substrate, the method comprising:
depositing material from one or more nozzles to form a grid of metallization lines on the crystalline semiconductor substrate, wherein the grid includes a metallization line having a variable height.

2. The method of claim 1, wherein at least one of the metallization lines has variable width.

3. The method of claim 1, comprising:
generating image data corresponding to the grid of metallization lines wherein the metallization line having the variable height is designed according to an amount of electrical current flow intended to be carried by the line,
wherein depositing the material on the semiconductor substrate is done according to the image data.

4. The method of claim 3, comprising:
detecting characteristics of the crystalline semiconductor substrate, the substrate being a polycrystalline semiconductor substrate, the characteristics being at least one of grain boundaries of the substrate, size of the substrate and spatial variations in sheet resistance or the minority carrier lifetime of the substrate, wherein the image data is generated based on the characteristics of the substrate.

5. (canceled)

6. The method of claim 1, wherein depositing said material is performed using a digital inkjet head.

7-10. (canceled)

11. The method of claim 4, wherein detecting characteristics of the substrate and generating the image data is done in real-time.

12. (canceled)

13. The method of claim 1, wherein a cross section of the the metallization line having the variable height is shaped as a wedge.

14-15. (canceled)

16. The method of claim 1, wherein the semiconductor substrate is a solar cell.

17. The method of claim 16, comprising:
calculating optimal pattern of the metallization lines with respect to solar cell efficiency given a certain amount of material to be deposited.

18. The method of claim 1, wherein the metallization line having the variable height is deposited in layers and the number of layers is determined according to a desired variable height.

19. The method of claim 1, wherein the metallization line having the variable height is tapered.
